(19) United States
(12) Patent Application Publication
(10) Pub. No.: US 2004/0128607 A1
(43) Pub. Date: Jul. 1, 2004

(54) Method and apparatus to encode linear block codes

(76) Inventor: Ilan Sutskover, Hadera (IL)

Correspondence Address: EITAN, PEARL, LATZER & COHEN ZEDEK LLP, 10 ROCKEFELLER PLAZA, SUITE 1001, NEW YORK, NY, 10020, US

(21) Appl. No.: 10/331,635

(22) Filed: Dec. 31, 2002

(51) Int. Cl. H03M 13/00

(52) U.S. Cl. 714/759

(57) ABSTRACT

Briefly, a method of encoding a linear block code including receiving an input word and computing at least a significant portion of a codeword of the linear block code by applying a sequence of operations including at least one forward substitution using a lower triangular matrix derived from a sub-matrix of a parity check matrix of the linear block code and at least one backward substitution using an upper triangular matrix derived from the sub-matrix.

### BACKGROUND OF THE INVENTION

Error correction, using an error correction code, improves the reliability communication systems and devices. In existing encoding methods, an encoder at the transmission end of a communication encodes an input word, for example, a block or vector of a given length, to produce a codeword of the error correction code. A decoder at the receiving end of the communication decodes a received word (block), yielding an estimation of the codeword that may indicate the original input word. A linear block code, C, having length n, may be described by a parity-check matrix, H_{m×n}, whose null space is block code C. Alternatively, block code C may be described by a generator matrix G_{k×m}, wherein k+m=n, whose rows span all the codewords of code C. During the encoding process, an information sequence v=(v₁, . . . ,vₖ) is encoded to yield a corresponding codeword, x=(x₁, . . . ,xₙ), in which k elements may represent the input word (block), for example, (x₁, . . . ,xₖ)=(v₁, . . . ,vₖ), and the remaining m elements may represent a new block, for example, (xₖ₊₁, . . . ,xₙ) (p₁, . . . ,pₘ). Such encoding may generally be performed by applying generator matrix G to word v to produce x. This encoding method typically requires a number of numerical operations on the order of O(n²), which may be prohibitively complex for large block lengths, for example, n≧10,000.

Block codes having sparse parity check matrices are known in the art by the name of Low-Density Parity-Check (LDPC) codes. Such block codes may provide excellent decoding performance. For LDPC codes, an encoder was proposed in Richardson and Urbanke, “Efficient encoding of low-density parity-check codes”, IEEE Transactions on information theory, Vol.47, No.2, pp.638-656, February 2001. (“the RU encoder”). However, this encoder is not efficient for encoding certain classes of LDPC codes. For example, the RU encoder is not useful for classes (for example, ensembles) of LDPC codes where only a small fraction of the columns of matrix H, for example, up to one percent of the columns, or none of the columns, contain exactly 2 non-zero entries. Such ensembles are referred to herein as 2-=0 classes or ensembles of LDPC codes.

There are also specific solutions known in the art for encoding additional classes of LDPC codes, for example, codes based on finite geometries. However, such additional classes are of less interest in most cases, for example, because they do not provide the code-design flexibility generally enabled by LDPC codes.

There is thus a need for an encoding method having a low computational complexity, for example, of order O(n), suitable for encoding a broad range of LDPC codes.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features and advantages thereof, may best be understood by reference to the following detailed description when read with the accompanied drawings in which:

FIG. 1 is a schematic block diagram of a communication system including at least one communication device in accordance with exemplary embodiments of the present invention;

FIG. 2 is a schematic block diagram illustrating an encoder in accordance with exemplary embodiments of the invention; and

FIG. 3 is a schematic block diagram of a method of encoding linear block codes in accordance with exemplary embodiments of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following detailed description, numerous specific details are set forth in order to provide a thorough understanding of the invention. However it will be understood by those of ordinary skill in the art that the present invention may be practiced without these specific details. In other instances, well-known methods, procedures, components and circuits have not been described in detail so as not to obscure the present invention.

Some portions of the detailed description that follows are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

Unless specifically stated otherwise, as apparent from the following discussions, it is appreciated that throughout the specification discussions utilizing terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

It should be understood that embodiments of the present invention may be used in variety of applications. Although the scope of the present invention is not limited in this respect, the circuits and techniques disclosed herein may be used in many apparatuses such as receivers of a radio system. Receivers intended to be included within the scope of the present invention include, by a way of example only, cellular radiotelephone receivers, spread spectrum receivers, digital system receivers and the like.

Types of cellular radiotelephone receivers intended to be within the scope of the present invention include, although not limited to, Code Division Multiple Access (CDMA), CDMA 2000 and wideband CDMA (WCDMA) cellular radiotelephone, receivers for receiving spread spectrum signals, and the like.

Devices, systems and methods incorporating aspects of embodiments of the invention are also suitable for computer communication network applications, for example, intranet and Internet applications. Embodiments of the invention may be implemented in conjunction with hardware and/or software adapted to interact with a computer communication network, for example, a local area network (LAN), wide area network (WAN), or a global communication network, for example, the Internet. As is known in the art, the use of LDPC ensembles of error correction codes may be particularly advantageous in such applications.

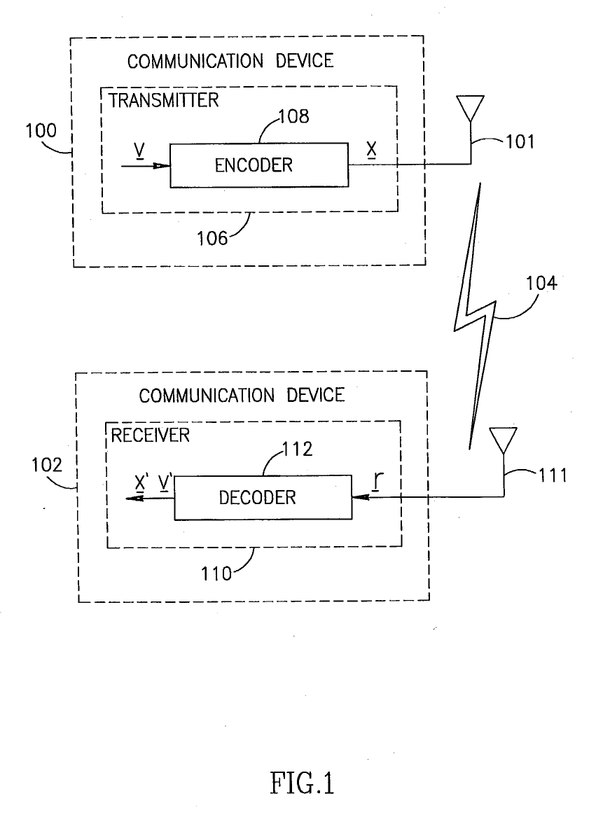

FIG. 1 is a simplified block-diagram illustration of an exemplary communication system, in accordance with some embodiments of the present invention. A communication device 100 is able to communicate with a communication device 102 over a communication channel 104.

Although the scope of the present invention is not limited in this respect, communication devices 100, 102 may comprise wire or wireless or cable modems of computers and communication channel 104 may be a wide-area-network (WAN) or local-area-network (LAN). For example, the system may be a wireless LAN system or a digital subscriber line (DSL) system. Alternatively, although the scope of the present invention is not limited in this respect, the communication system shown in FIG. 1 may be part of a cellular communication system, with one of communication devices 100, 102 being a base station and the other a mobile station or with both communication devices 100, 102 being mobile stations, a pager communication system, a personal digital assistant (PDA) and a server, etc. In such cases, although the scope of the present invention is in no way limited in this respect, communication devices 100 and 102 may each comprise a radio frequency antenna, 101 and 111, respectively, as is known in the art. In the case of a cellular wireless communication system, according to some embodiments of the invention, the communication system shown in FIG. 1 may be a 3^{rd} Generation Partnership Project (3GPP), such as, for example, Frequency Domain Duplexing (FDD), Wideband Code Division Multiple Access (WCDMA) cellular system and the like.

Communication device 100 may comprise a transmitter 106, which may comprise an encoder 108 in accordance with embodiments of the invention, as described in detail below. Communication device 102 may comprise a receiver 110, which may comprise a decoder 112.

Encoder 108 may encode an input word (for example, a block or vector) v, based on a linear block code, to produce a codeword, x, as described in detail below. The linear block code may be represented by a parity-check matrix, H, as described below. Codeword x may be modulated, up-converted and transmitted through communication channel 104, which may be a noisy channel, as is known in the art.

Receiver 110 may receive a signal from communication channel 104, which signal, after down-conversion and demodulation, may be identified as a received word, r. Although the scope of the present invention is not limited in this respect, the noise from communication channel 104 may be an additive noise, and received word r may thus be represented by r=x+noise. As is known in the art, decoder 112 may use the parity-check matrix in an attempt to determine from received word r a word v′ (or codeword x′) that should correspond to the original word v (or codeword x) encoded by encoder 108.

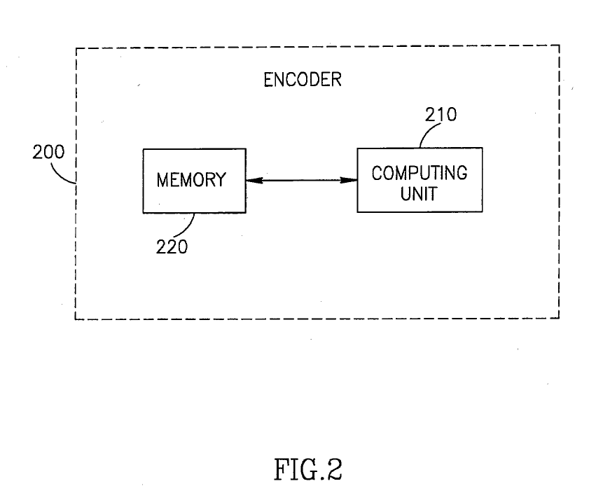

Methods according to some embodiments of the present invention may be implemented in encoders using software, hardware or any suitable combination of software and/or hardware in accordance with specific implementations of embodiments of the invention. FIG. 2 is a simplified block-diagram illustration of an exemplary encoder 200, in accordance with some embodiments of the present invention. Encoder 200 may comprise a computing unit 210 and a memory 220 coupled to computing unit 210. Although the scope of the present invention is not limited in this respect, computing unit 210 may be an application specific integrated circuit (ASIC), a reduced instruction set circuit (RISC), a digital signal processor (DSP) or a central processing unit (CPU). Instructions to enable computing unit to perform methods of embodiments of the present invention may be stored in memory 220.

Encoder 200 may implement an encoding algorithm using components of a sparse parity check matrix, H. The encoding method according to embodiments of the invention, as described below, enables encoding of various classes of Low-Density Parity-Check (LDPC) codes, for example, λ₂≅0 ensembles of LDPC, as well as encoding of other classes of LDPC codes, while maintaining a low computational complexity, for example, on the order of O(n). The encoding method according to embodiments of the present invention may also be used for encoding of codes whose parity check matrix may not be sparse, but where, for example, a sub-matrix derived from the parity check matrix may be sparse. However, embodiments of the invention may also be suitable for encoding of codes whose parity-check matrix may not have a sparse sub-matrix.

It will be appreciated by persons skilled in the art that embodiments of the present invention, using devices and methods as described herein, provide an encoder for encoding LDPC codes, which codes may be randomly selected over a given ensemble. Furthermore, the encoder in accordance with embodiments of the invention may provide a solution with a computational complexity on the order of O(n) for encoding LDPC codes of classes having a low block error rate, for example, a block error rate on the order of the bit error rate, for example, λ₂≅0 type ensembles.

Variations of encoders according to embodiments of the present invention have been simulated successfully, demonstrating the low computational complexity, i.e., O(n), made possible by embodiments of the present invention.

In accordance with embodiments of the invention, encoder 200 may have stored therein, or in the memory 220 associated therewith, a Lower/Upper (LU) decomposition of a sub-matrix derived from H, for example, a sub-matrix representing non-systematic symbols of the code being encoded. As discussed below, the LU decomposition operation may be performed offline, for example, using decomposition methods as are known in the art. It will be appreciated that, once a suitable LU decomposition is obtained, the decomposed elements may be used repeatedly by the encoder. Therefore, the complexity of computation involved in deriving a suitable decomposition of H is generally inconsequential to the computational complexity of the method of some embodiments of the present invention.

As is known in the art, systematic encoding (mapping) refers to any encoding process in which the equation (xⱼ₁, . . . ,xⱼₖ)=(v₁, . . . ,vₖ) is satisfied for all vectors v=(v₁, . . . ,vₖ) and for a certain sub-group of coordinates {j₁, . . . ,jₖ} being mapped. As is known in the art, for any given mapping of any linear block code, there exists a corresponding systematic mapping with the same performance. Thus, the parity check matrix H in accordance with some embodiments of the invention may be represented in the form:

H32 (A|B) (1)

wherein A_{m×k} corresponds to the systematic part and B_{m×m} is an invertible matrix corresponding to the non-systematic part. In this representation, matrix A constitutes the first k columns of H and matrix B constitutes the remaining columns. It should be further noted that if matrix H is sparse, then matrices A and B must also be sparse.

According to an embodiment of the invention, rearranging and rewriting the elements in matrix H in the form (x₁, . . . ,xₖ, xₖ₊₁, . . . , xₙ)=(v₁, . . . ,vₖ,xₖ₊₁, . . . ,xₙ), it may be shown that, for any valid codeword, the following equation holds:

−A(v₁, . . . ,vₖ)^{t}=B(xₖ₊₁, . . . ,xₙ)^{t} (2)

where t represents the transpose.

By calculating a first vector s, defined by the matrix equation (s₁, . . . ,sₘ)=−A(v₁, . . . ,vₖ)^{t}, the matrix equation B(xₖ₊₁, . . . ,xₙ)=(s₁, . . . ,sₘ) may be solved to obtain the non-systematic symbols (xₖ₊₁, . . . ,xₙ), also referred to herein as p=(p₁, . . . ,pₘ)

A lower triangular matrix is a matrix with entries aᵢⱼ such that if j>i then aᵢⱼ=0. An upper triangular matrix is a matrix with entries aᵢⱼ such that if j<i then aᵢⱼ=0.

If matrix B, or any sub-matrix (for example, B′) of B, has at least one LU decomposition, namely, LU_{m×m}U_{m×m}=B, where L is a lower triangular matrix and U is an upper triangrilar matrix (or L_{l×l}U_{l×l}=B′, where l<m), then the following two equations hold:

L(z₁, . . . ,zₘ)^{t}=(s₁, . . . ,sₘ)^{t} (3)

and

U(xₖ₊₁, . . . ,xₙ)^{t}=(z₁, . . . ,zₘ)^{t} (4)

wherein a second vector Z=(z₁, . . . ,zₘ) is introduced as defined by Equations 3 and 4.

It is noted that matrix B, or sub-matrix B′, may have more than one possible LU decomposition, in which case any valid LU decomposition may be used for encoding according to embodiments of the invention. For the purposes of this detailed description, a LU decomposition of a given matrix refers to any decomposition where a lower triangular component and an upper triangular component, neither of which is a unity matrix, are derived from the given matrix. It is further noted that matrices L, U and B′ are not necessarily square matrices. Similarly, sub-matrix B′ is not necessarily invertible.

It is further noted that the separation of matrix H into matrices A and B is demonstrated for explanatory proposes only and is in no way intended to limit the scope of the present invention. For example, in alternative embodiments of the invention, matrices L and U may be derived from any other LU-decomposable sub-matrix of H. Furthermore, any other method of deriving at least one lower triangular matrix (L) and at least one upper triangular matrix (U) from parity-check matrix H may be used in conjunction with alternative embodiments of the present invention. For example, a sub-matrix of H may be decomposed using an Upper/Lower (UL) decomposition similar to the LU decomposition described herein. In another example, a decomposition of the form LDU or UDL, where D is a diagonal matrix, may be derived from parity-check matrix H. In a farther example, a decomposition of the form ALBUC may be derived from parity-check matrix H. It will be appreciated by persons of ordinary skill in the art how to modify Equations (3) and (4) according to the precise derivation of L and U from parity-check matrix H.

The process of uncovering an appropriate LU-decomposable matrix B, or sub-matrix of B, according to embodiments of the invention, may involve a complexity higher than the order of O(n). However, as discussed above and below, such complex calculations (if necessary) may be performed only once, typically off-line, and therefore, such calculations do not affect the computational complexity of the encoding process.

As is known in the art, an equation of the form Lz=s, such as Equation 3 above, may be solved by means of forward substitution, and an equation of the form Ux=z, such as Equation 4 above, may be solved by means of backward substitution. In the example above, if matrices A, L and U are all sparse, then the following computation complexities hold:

multiplication of input word v by matrix A, to obtain first vector s, requires a number of operations on the order of O(n);

solving Equation 3 for elements z₁, . . . ,xₘ of second vector z, using forward substitution, as is known in the art, requires a number of operations on the order of O(n); and

solving Equation 4 for elements xₖ₊₁, . . . ,xₙ, also denoted p=(p₁, . . . ,pₘ), using backward substitution, as is known in the art, requires a number of operation on the order of O(n).

There are well known solutions in the theory of sparse matrices for the general mathematical problem of solving sparse linear equations using LU decomposition, i.e., for solving a sparse linear equation system by LU decomposition. Further, as is known in the art, for example, as explained in C. Fu, X Jiao and T. Yang, “Efficient sparse LU factorization with partial pivoting on distributed memory architectures”, IEEE Transactions on parallel and distributed systems, Vol. 9, No.2, pp. 109-125, February 1998, if matrix H is sparse (and thus sub-matrix A is also sparse), it is likely that a sparse LU decomposition of H, i.e., a decomposition in which triangular matrices L and U are also sparse, may be obtained.

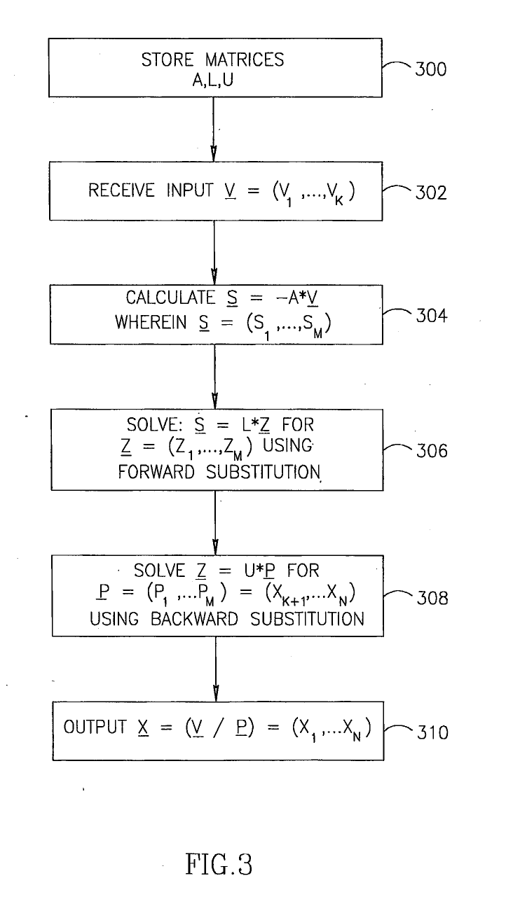

Referring to the schematic flow chart of FIG. 3, a method of encoding a linear block code according to embodiments of the present invention is shown. As indicated at block 300, prior to implementing the encoder of embodiments of the present invention, pre-calculated data representing sub-matrices A, L and U may be stored in memory, for example, memory 220 of encoder 200 (FIG. 2), or otherwise made available to encoder 200.

As indicated at block 302, the method in accordance with embodiments of the invention may begin with receiving input word v=(v₁, . . . ,vₖ), which may be a vector representing a non-encoded word.

Then, as indicated at block 304, first vector s=(s₁, . . . ,sₘ) may be obtained by multiplying word v by the negative of the systematic-part matrix, −A, as defined above.

As indicated at block 306, the elements of second vector z, as defined above, may be obtained by solving the equation s=Lz for z₁, . . . ,zₘ, using forward substitution, as discussed above.

Then, as indicated at block 308, vector A, representing the unsystematic elements xₖ₊₁, . . . ,xₙ of codeword x, may be obtained by solving the equation z=Up for p₁, . . . , pₘ, using backward substitution, as discussed above.

Finally, as indicated at block 310, the method may generate a codeword x (v|p), including both the original non-encoded block, represented by sub-vector v, as well as the new encoded elements, represented by sub-vector p. The method may then generate an output signal corresponding to codeword x=(x₁, . . . ,xₙ). The output signal may then be further processed and transmitted via a communication network, for example, as described above with reference to FIG. 1.

As mentioned above, a method in accordance with embodiments of the invention may include the preliminary stage of decomposing a sparse LDPC matrix H to obtain sparse A, L and U matrices, or any other matrices or sub-matrices derived from H, having similar properties. Such a system has been simulated successfully. It will be appreciated by persons skilled in the art that the process of obtaining sparse A, L and U matrices from a given sparse LDPC matrix H in accordance with embodiments of the invention is a preliminary stage of the encoding process, i.e., it may be carried out only once per code and, therefore, the computational complexity of this stage is not significant to the actual encoding process. Further, this decomposition process may be performed off-line.

The encoder of FIG. 2 and the encoding method of FIG. 3 describe exemplary implementation of encoders in accordance with embodiments of the invention. However, it should be appreciated that various other encoder designs and encoding methods are also within the scope of the present invention, for example, any encoder or encoding method utilizing the sparseness of parity check matrix H by applying a sparse decomposition comprising at least one lower triangular matrix L and at least one upper triangular matrix U, either to an m×m matrix or to any l×l sparse matrix deduced from H, wherein l<m. It will be appreciate that the encoder of FIG. 1 falls into this category of encoders in accordance with embodiments of the invention.

It will be appreciated by persons skilled in the art that, the encoder of embodiments of the present invention provides a significantly improved encoder for various classes of codes, for example, LDPC codes of λ₂≅0 classes (i.e., λ₂≅0 ensembles), using a sparse parity check matrix. Such classes of LDPC codes are useful in many coding applications, for example, Internet-related coding applications. Furthermore, the encoder of embodiments of the invention may be useful for encoding other categories of LDPC codes in addition to LDPC codes defined above, as well as for additional types of codes. Furthermore, the encoder of embodiments of the invention may be used in conjunction with non-sparse parity-check matrices.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A method comprising:
based on an input word, computing a first intermediate vector using a first non-unity triangular matrix derived from a parity check matrix of a code; and
computing a second intermediate vector based on said first intermediate vector and a second non-unity triangular matrix derived from said parity check matrix, wherein one of said first matrix and said second matrix is a lower triangular matrix and the other of said first matrix and said second matrix is an upper triangular matrix.

2. The method of claim 1, further comprising:
generating a codeword of said code, said codeword including said input word and said second intermediate vector.

3. The method of claim 1, further comprising:
computing a third intermediate vector by applying a systematic part of said parity-check matrix to said input word,
wherein computing said first intermediate vector comprises computing said first intermediate vector based on said third intermediate vector and said first triangular matrix.

4. The method of claim 1, wherein computing said first intermediate vector comprises computing said first intermediate vector using forward substitution, and wherein computing said second intermediate vector comprises computing said second intermediate vector using backward substitution.

5. The method of claim 1, wherein said code is a low-density parity-check code.

6. The method of claim 5, wherein said low-density parity-check code is a class λ₂≅0 low-density parity-check code.

7. The method of claim 1, wherein said lower triangular matrix is a component of a sub-matrix of said parity check matrix and said upper triangular matrix is another component of said sub-matrix.

8. The method of claim 7, wherein said sub-matrix is substantially sparse.

9. An apparatus comprising:
an encoder to compute at least a portion of a codeword of a code based on an input word, a non-unity lower triangular matrix, and a non-unity upper triangular matrix, the lower triangular matrix and the upper triangular matrix both derived from a parity-check matrix of the code.

10. The apparatus of claim 9, wherein said lower triangular matrix is a component of a sub-matrix of said parity check matrix and said upper triangular matrix is another component of said sub-matrix.

11. The apparatus of claim 9, wherein said encoder further comprises circuitry for transmitting said codeword.

12. The apparatus of claim 9, further comprising a memory associated with said encoder to store said lower triangular matrix and said upper triangular matrix.

13. A communication device comprising:
transmission circuitry; and
an encoder comprising a computing unit to compute at least a portion of a codeword of a code based on an input word, a non-unity lower triangular matrix, and a non-unity upper triangular matrix, the lower triangular matrix and the upper triangular matrix both derived from a parity-check matrix of the code.

14. The communication device of claim 13, further comprising:
a memory coupled to said computing unit, said memory able to store therein a representation of said lower triangular matrix and said upper triangular matrix.

15. The communication device of claim 14, wherein said computing unit comprises a digital signal processor.

16. The communication device of claim 13, wherein said lower triangular matrix is a component of a su-b-matrix of said parity check matrix and said upper triangular matrix is another component of said sub-matrix

17. A communication system comprising:
a first communication device to transmit through a communication channel a signal including a codeword of a linear block code, said communication device comprising an encoder comprising a computing unit to compute at least a portion of a codeword of a code based on an input word, a non-unity lower triangular matrix, and a non-unity upper triangular matrix, the lower triangular matrix and the upper triangular matrix both derived from a parity-check matrix of the code; and
a second communication device able to receive said signal.

18. The communication system of claim 17, wherein said lower triangular matrix is a component of a sub-matrix of said parity check matrix and said upper triangular matrix is another component of said sub-matrix

19. The communication system of claim 17, wherein said communication channel is a wide-area-network and said first communication device comprises a modem.

20. The communication system of claim 17, wherein said communication channel is a local-area-network and said first communication device comprises a modem.

21. The communication system of claim 17, wherein said signal is a radio frequency signal.

22. A communication system comprising:
a communication device to transmit through a communication channel a signal including a codeword of a linear block code, said communication device comprising an encoder comprising a computing unit to compute at least a portion of a codeword of a code based on an input word, a non-unity lower triangular matrix, and a non-unity upper triangular matrix, the lower triangular matrix and the upper triangular matrix both derived from a parity-check matrix of the code; and
a Wideband Code Division Multiple Access communication device able to receive said signal.

23. The communication system of claim 22, wherein said code is a low-density parity-check code.

24. An article comprising a storage medium having stored thereon instructions that, when executed by a computing platform, result in:
based on an input word, computing a first intermediate vector using a first non-unity triangular matrix derived from a parity-check matrix of a code; and
computing a second intermediate vector based on said first intermediate vector and a second non-unity triangular matrix derived from said parity check matrix, wherein one of said first matrix and said second matrix is a lower triangular matrix and the other of said first matrix and said second matrix is an upper triangular matrix.

25. The article of claim 24, wherein the instructions, when executed, further result in:
generating a codeword of said code, said codeword including said input word and said second intermediate vector.

26. The article of claim 24, wherein the instructions, when executed, further result in:
computing a third intermediate vector by applying a systematic part of said parity-check matrix to said input word,
wherein computing said first intermediate vector comprises computing said first intermediate vector based on said third intermediate vector and said first triangular matrix.

27. The article of claim 24, wherein said lower triangular matrix is a component of a sub-matrix of said parity check matrix and said upper triangular matrix is another component of said sub-matrix.

28. The article of claim 27, wherein said sub-matrix is substantially sparse.

29. The article of claim 24, wherein computing said first intermediate vector comprises computing said first intermediate vector using forward substitution, and wherein computing said second intermediate vector comprises computing said second intermediate vector using backward substitution.

30. The article of claim 24, wherein said code is a low-density parity-check code.

31. The article of claim 30 wherein said low-density parity-check code is a class λ₂≅0 low-density parity-check code.
